(19) United States
(12) Patent Application Publication
(10) Pub. No.: US 2003/0054628 A1
(43) Pub. Date: Mar. 20, 2003

(54) Method of forming a low resistance multi-layered TiN film with superior barrier property using poison mode cycling

(75) Inventors: Xavier Seah Teo Leng, Singapore (SG); Fu Chang, Singapore (SG); Johnny Kuei Chih, Singapore (SG)

Correspondence Address: GEORGE O. SAILE & ASSOCIATES, 28 DAVIS AVENUE, POUGHKEEPSIE, NY, 12603, US

(73) Assignee: Chartered Semiconductor Manufacturing Ltd.

(21) Appl. No.: 09/953,545

(22) Filed: Sep. 17, 2001

(51) Int. Cl. H01L 21/4763; H01L 21/44

(52) U.S. Cl. 438/622; 438/643; 438/648; 438/687

(57) ABSTRACT

A new method of forming a robust titanium nitride barrier layer by PVD is described. Semiconductor device structures are provided in and on a semiconductor substrate. The semiconductor device structures are covered with an insulating layer. A via is opened through the insulating layer to one of the underlying semiconductor device structures. A titanium nitride barrier layer having a discontinuous grain structure is deposited within the via wherein the titanium nitride barrier layer comprises alternating layers of titanium nitride and titanium containing a trace of nitrogen. A metal layer is deposited overlying the titanium nitride barrier layer wherein the discontinuous grain structure of the titanium nitride barrier layer prevents diffusion from the metal layer into the insulating layer to complete formation of a robust titanium nitride barrier layer in the fabrication of an integrated circuit device.

### BACKGROUND OF THE INVENTION

(1) Field of the Invention

The invention relates to a method of barrier layer formation in the fabrication of integrated circuits, and more particularly, to a method of forming an improved barrier layer with decreased sheet resistivity in the manufacture of integrated circuits.

(2) Description of the Prior Art

In a common application for integrated circuit fabrication, a contact/via opening is etched through an insulating layer to an underlying conductive area to which electrical contact is to be made. A barrier layer, typically titanium/titanium nitride, is formed within the contact/via opening followed by the metal layer. Physical vapor deposition (PVD) of titanium nitride (TiN) has been the choice of barrier metal for 0.5 to 0.30 μm technology nodes. TiN has usually been deposited by sputtering a pure titanium target in a nitrogen (N₂) ambient to produce a strongly <111> textured TiN film. Unfortunately, the PVD TiN also displays a highly columnar grain structure that offers a fast diffusion path for fast moving species such as fluorine from tungsten deposition or copper atoms in the case of copper metallization. This grain structure obviously is undesirable for PVD TiN as a barrier metal.

U.S. Pat. No. 5,240,880 to Hindman et al discloses a Ti/TiN/Ti layer formed by turning off and on N₂ gas. U.S. Pat. No. 6,007,684 to Fu et al teaches forming Ti, TiO, and TiN layers by turning on and off different gases. U.S. Pat. No. 6,045,666 to Satitpunwaycha et al forms a Ti/TiN layer including a graded TiNₓ layer forming by cutting off N₂ gas wherein the nitrogen is gradually depleted until pure titanium is formed. U.S. Pat. No. 5,738,917 to Besser et al forms a Ti/TiN/Ti layer by turning on and off N₂ gas. U.S. Pat. No. 5,747,879 to Rastogi et al teaches forming a capping layer of Ti/TiN over the metal layer by turning on and off N₂ gas in a controlled way. U.S. Pat. Nos. 6,057,231 to Givens et al and 5,391,517 to Gelatos et al teach methods of forming Ti/TiN/Ti layers. U.S. Pat. No. 5,981,380 to Trivedi et al shows forming a TiN barrier layer by sputtering a TiN target. U.S. Pat. No. 5,895,266 to Fu et al teaches various combinations of gases and powers to form titanium layers.

### SUMMARY OF THE INVENTION

A principal object of the present invention is to provide an effective and very manufacturable method of forming a robust barrier layer in the fabrication of integrated circuit devices.

Another object of the invention is to provide a method for forming a robust titanium nitride barrier layer.

A further object of the invention is to form a robust titanium nitride barrier layer by physical vapor deposition (PVD) in the fabrication of integrated circuits.

Yet another object of the invention is to provide a method for forming a robust titanium nitride barrier layer by PVD without a columnar grain structure.

Yet another object of the invention is to provide a method for forming a titanium nitride barrier layer by PVD without a columnar grain structure that will reduce via/contact resistance.

In accordance with the objects of this invention a new method of forming a robust titanium nitride barrier layer by PVD is achieved. Semiconductor device structures are provided in and on a semiconductor substrate. The semiconductor device structures are covered with an insulating layer. A via is opened through the insulating layer to one of the underlying semiconductor device structures. A titanium nitride barrier layer having a discontinuous grain structure is deposited within the via wherein the titanium nitride barrier layer comprises alternating layers of titanium nitride and titanium containing a trace of nitrogen. A metal layer is deposited overlying the titanium nitride barrier layer wherein the discontinuous grain structure of the titanium nitride barrier layer prevents diffusion from the metal layer into the insulating layer to complete formation of a robust titanium nitride barrier layer in the fabrication of an integrated circuit device.

### BRIEF DESCRIPTION OF THE DRAWINGS

In the accompanying drawings forming a material part of this description, there is shown:

FIGS. 1, 5 and 6 schematically illustrate in cross-sectional representation a preferred embodiment of the present invention.

FIG. 2 schematically illustrates in cross-sectional representation a titanium nitride barrier layer having columnar grain boundaries.

FIG. 3 schematically illustrates in cross-sectional representation a titanium nitride barrier layer of the present invention having discontinuous grain boundaries.

FIG. 4 graphically illustrates the N₂ gas cycle and power cycle of the present invention.

### DESCRIPTION OF THE PREFERRED EMBODIMENTS

Referring now more particularly to FIG. 1, there is illustrated a portion of a partially completed integrated circuit device. There is shown a semiconductor substrate 10, preferably composed of monocrystalline silicon. Semiconductor devices structures are formed in and on the semiconductor substrate. For example, a gate electrode 16 and source/drain regions 14 are illustrated in FIG. 1. Source/drain region 14 is an N+ region in the illustration. It is well understand by those skilled in the art that this could be a P+ region as well. It should be understood that the invention is not limited to the embodiment illustrated in the drawing figures, but is applicable to any application in which metallization is used.

A silicide layer 18 may be formed on the gate electrode 16 and overlying the source/drain regions 14. This layer may be titanium silicide or cobalt silicide, or the like, and is formed by conventional methods.

An insulating layer 20, composed of silicon dioxide, borophosphosilicate glass (BPSG), borosilicate glass (BSG), phosphosilicate glass (PSG), or the like, is deposited over the surface of the silicided semiconductor structures to a thickness of between about 5000 to 9000 Angstroms and preferably planarized. A contact/via opening or a dual damascene opening 22 is etched through the insulating layer 20 to the silicide layer 18 overlying the source/drain region 14 within the semiconductor substrate.

It will be understood by those skilled in the art that the process of the present invention for forming a titanium nitride barrier layer for metallization can be performed at any level of metallization, not only for the first level metallization illustrated here.

The fabrication of the robust titanium nitride barrier layer of the present invention will now be described. The novel fabrication method has been coined “poison mode cycling.” The so-called poison mode is defined as a mode in which titanium nitride is sputter deposited by nitriding a titanium target, such as by a flow of N₂ gas. In the poison mode cycling process of the present invention, an intended disruption in N₂ flow (which nitrides the target) at intervals achieves a disruption in the columnar structure formation of the barrier layer.

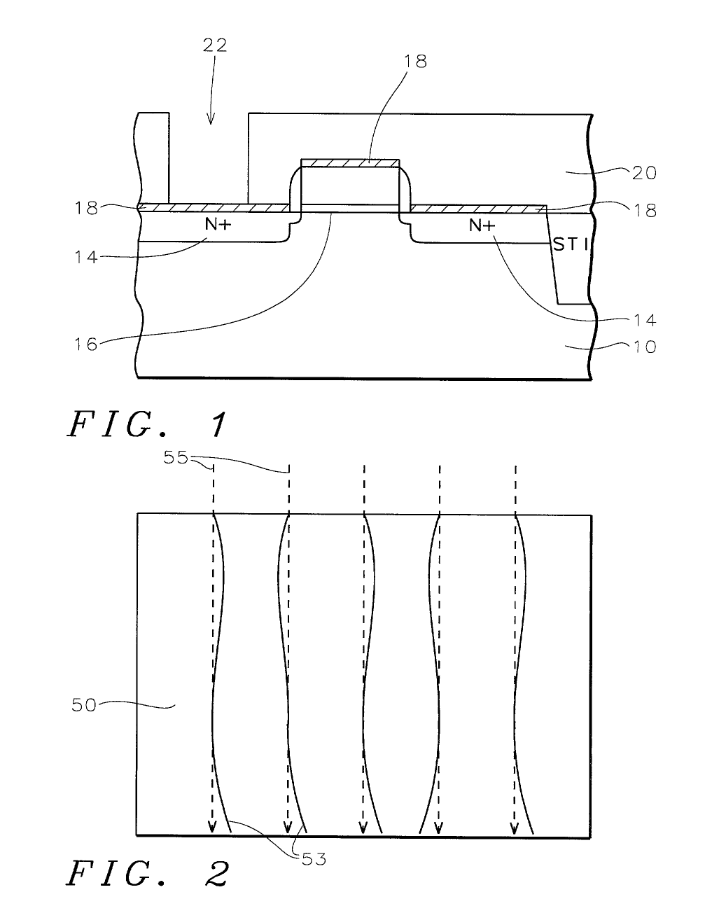

FIG. 2 illustrates a typical PVD titanium nitride layer showing the highly columnar structure of this layer. The wavy lines 53 represent the outlines of the grain boundaries in the titanium nitride barrier layer 50. The dotted lines 55 show the movement of ions or atoms through the columnar grain structure. Fast diffusing species such as copper and fluorine from WF₆ can move rapidly along the columnar structure, as seen in FIG. 2. Thus, the barrier layer depicted in FIG. 2 will not be an effective barrier due to its columnar structure. For example, in forming a tungsten plug in a via, WF₆ is used to deposit tungsten. The WF6 introduces fluorine species through the barrier layer into an underlying conductive layer such as aluminum. The fluorine subsequently forms a highly resistive AlF₃ compound. In another example, copper from an AlCu metal plug can diffuse through the barrier layer and cause silicon/junction spiking in the substrate or voiding into the underlying metal layer.

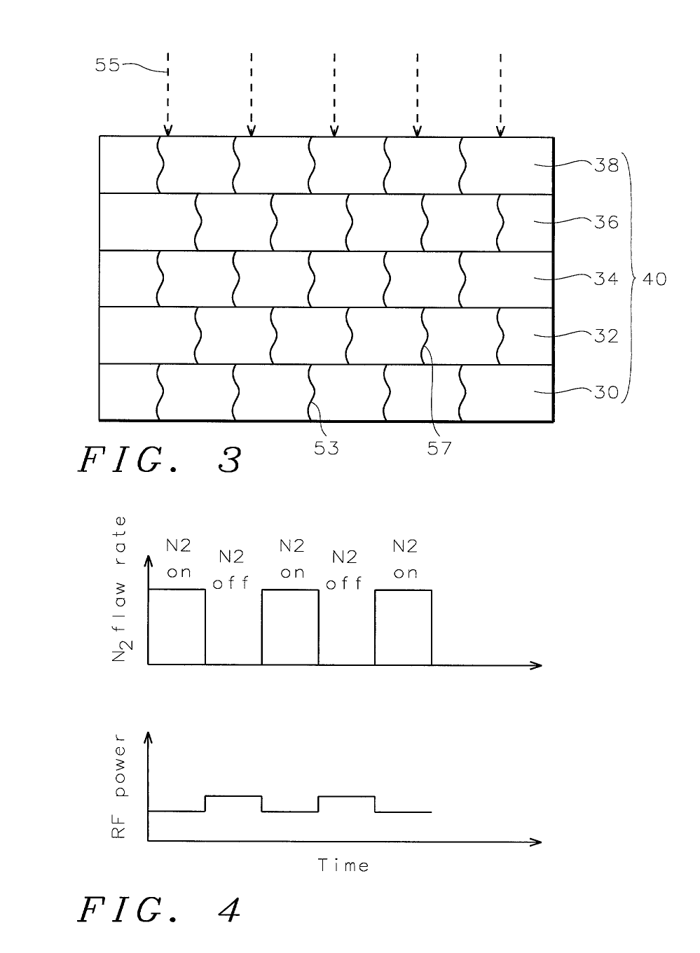

FIG. 3 illustrates the novel barrier layer of the present invention. The barrier layer of the invention is deposited by physical vapor deposition (PVD) in a single chamber. The technique, called “poison mode cycling,” involves cutting off N₂ gas flow at certain time intervals during PVD TiN deposition to create a multi-layer TiN barrier metal film. Using this technique, “dirty Ti” is inserted between TiN layers. “Dirty Ti” refers to sputtered titanium containing slight traces of nitrogen, about 30%. The “dirty Ti” insertion effectively causes a discontinuous grain growth for titanium nitride to avoid the build up of a columnar structure.

For example, FIG. 3 illustrates a possible embodiment of poison mode cycling to form a multiple “dirty Ti” sandwich layer. For example, a 50 second sputtering time can be divided into five 10 second intervals. For the first interval, N₂ gas is flowed in the sputterer. TiN layer 30 is formed in this time period. This layer has the same columnar structure 53 as the prior art TiN layers. During the next interval, N₂ flow is turned off. During this interval, a “dirty Ti” layer 32 is formed overlying the first TiN layer. The “dirty Ti” layer 32 is essentially a titanium layer with a trace of leftover nitrogen. Because of the different composition of this layer from the underlying layer, the grain boundaries 57 in layer 32 will not align with the grain boundaries 53 in layer 30. Now, the N₂ gas is turned back on for the third interval, resulting in the deposition of TiN layer 34. Grain growth is dependent on the underlying layer. The “dirty Ti” layer has a smaller grain size than the TiN layer; thus the grain boundaries in layer 34 will not line up with the grain boundaries in layer 32.

During the fourth interval, N₂ flow is turned off. During this interval, a “dirty Ti” layer 36 is formed overlying the first TiN layer. The “dirty Ti” layer 36 is essentially a titanium layer with a trace of leftover nitrogen. Because of the different composition of this layer from the underlying layer, the grain boundaries in layer 36 will not align with the grain boundaries in layer 34. Now, the N₂ gas is turned back on for the fifth and final interval, resulting in the deposition of TiN layer 38.

In the process of the present invention, power is increased during the “dirty Ti” cycle to deplete the residual N₂ gas faster so as to achieve a rapid transition or change in grain size and orientation into a “dirty Ti” layer having a smaller grain size than the TiN layer. Thus, the “dirty Ti” layer serves as a distinctly different underlayer to disrupt the formation of a full columnar structure in the TiN barrier layer. FIG. 4 illustrates the N₂ gas cycle in the upper graph and the corresponding power cycle in the lower graph. Typical process conditions are an N2 flow of about 72 sccm during N₂ on intervals and 0 sccm N₂ flow during N₂ off intervals. Each interval may be about 10 seconds in duration. Normal power is about 6.5 kilowatts while higher power is about 8 kilowatts.

The diffusing species 42 will be stopped within the first two layers since the columnar structure has been disrupted by the “dirty Ti” layers. Superior barrier metal property results, especially against WF₆ penetration during tungsten nucleation and against copper atoms diffusibility. Lower via or contact resistance and lower TiN sheet resistance. This leads to a better barrier metal layer and lower resistivity. The process of the present invention extends the use of PVD TiN into advanced technology such as 0.25 μm technology and copper metallization.

The improved barrier layer of the present invention is preferred over a barrier layer comprising alternating TiN and Ti layers because of better manufacturability. If pure Ti is used, this layer must be deposited in a separate chamber from the TiN deposition. This type of barrier layer will have a similar performance improvement, but much lower throughput than the barrier layer of the present invention.

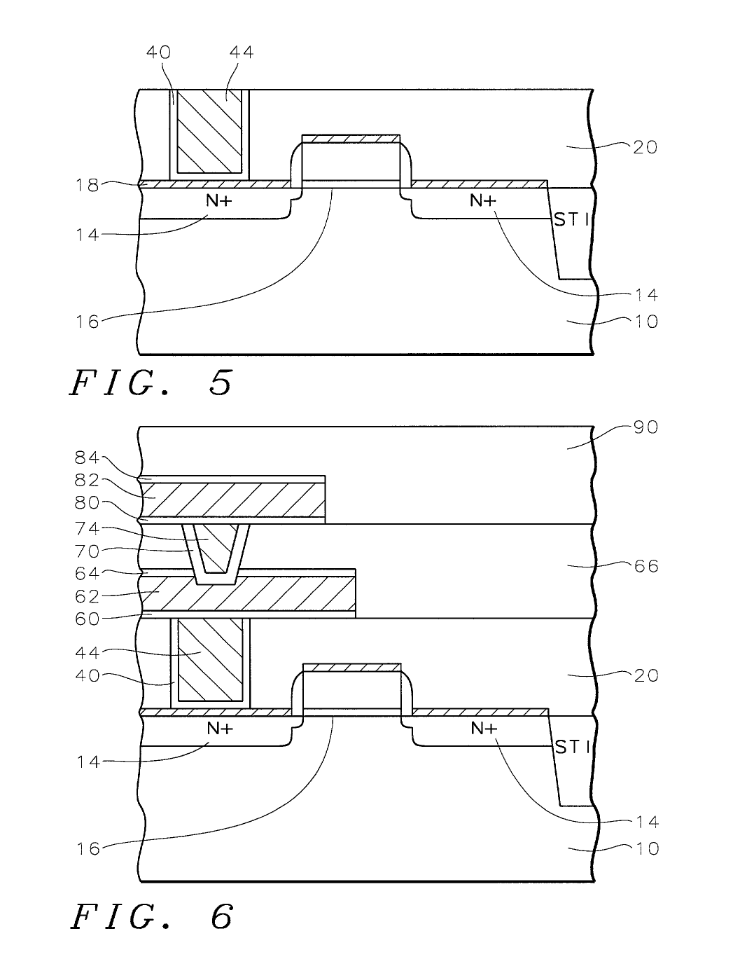

Referring now to FIG. 5, the novel TiN barrier layer of the present invention 40 has been formed within the contact/via opening. Now, a metal layer, such as tungsten or copper, for example, 44 is sputter deposited over the barrier layer to fill the contact/via opening. In the case of copper, a copper seed layer may be deposited by physical or chemical vapor deposition followed by electrochemical deposition of copper to fill a deep via hole. Diffusion into the dielectric layer 20 is prevented by the discontinuous grain structure of the titanium nitride barrier layer 40.

Processing continues as is conventional in the art to complete fabrication of the integrated circuit. The process of the present invention can be used at the contact or via levels. FIG. 5 illustrates metallization at the contact level. For example, FIG. 6 illustrates metallization at the via level. After forming the metal contact 44, a metal line is deposited and patterned. For example, the metal line comprises a Ti/TiN barrier layer 60, AlCu layer 62, and an antireflective coating (ARC) layer 64. Then an intermetal dielectric layer 66 is deposited over the metal line. A via opening is etched through the dielectric layer 66 to contact the metal line 64. The TiN barrier layer 70, formed by the poison mode cycling technique of the present invention, is formed within the via opening. A tungsten plug, for example, is formed by depositing tungsten into the via opening and etching back or planarizing the tungsten by chemical mechanical polishing (CMP). A second metal line, for example comprising a Ti/TiN barrier layer 80, AlCu layer 82, and ARC layer 84, is deposited and patterned, as shown. Passivation layer 90 covers the topmost metal line.

The process of the invention results in an effective and very manufacturable robust titanium nitride barrier for metallization. The TiN layer of the invention has a discontinuous grain structure, thereby preventing diffusion of species through the barrier layer.

While the invention has been particularly shown and described with reference to the preferred embodiments thereof, it will be understood by those skilled in the art that various changes in form and details may be made without departing from the spirit and scope of the invention.

What is claimed is:

1. A method of metallization in the fabrication of an integrated circuit device comprising:
providing semiconductor device structures in and on a substrate;
covering said semiconductor device structures with an insulating layer;
opening a via through said insulating layer to one of said underlying semiconductor device structures;
conformally depositing a titanium nitride barrier layer having a discontinuous grain structure within said via; and
depositing a metal layer overlying said titanium nitride barrier layer to complete said metallization in the fabrication of said integrated circuit device.

2. The method according to claim 1 wherein said semiconductor device structures include silicided gate electrodes and associated silicided source and drain regions.

3. The method according to claim 1 wherein said semiconductor device structures include silicided gate electrodes and associated silicided source and drain regions and lower level metallization.

4. The method according to claim 1 wherein said step of depositing said titanium nitride barrier layer comprises within a single sputtering chamber:
turning on a N₂ gas flow and thereby depositing a first layer of TiN within said via opening;
turning off said N₂ gas flow and thereby depositing a first titanium layer containing a trace of nitrogen overlying said first TiN layer; and
continuing a cycle of alternatingly turning on and off said N2 gas flow to form alternating layers of TiN and titanium containing a trace of nitrogen.

5. The method according to claim 4 wherein said during said step of turning on said N₂ gas flow, radio frequency power of a first rate is applied and wherein during said step of turning off said N₂ gas flow, radio frequency power of a second rate higher than said first rate is applied.

6. The method according to claim 5 wherein said first rate is about 6.5 kilowatts and wherein said second rate is about 8 kilowatts.

7. The method according to claim 1 wherein said discontinuous grain structure of said titanium nitride barrier layer prevents diffusion from said metal layer into said insulating layer.

8. The method according to claim 1 wherein said metal layer comprises tungsten.

9. The method according to claim 1 wherein said metal layer comprises copper.

10. The method according to claim 1 wherein said metal layer comprises AlCu.

11. A method of metallization in the fabrication of an integrated circuit device comprising:
providing semiconductor device structures in and on a substrate;
covering said semiconductor device structures with an insulating layer;
opening a via through said insulating layer to one of said underlying semiconductor device structures;
conformally depositing a titanium nitride barrier layer having a discontinuous grain structure within said via wherein said titanium nitride barrier layer comprises alternating layers of titanium nitride and titanium containing a trace of nitrogen; and
depositing a metal layer overlying said titanium nitride barrier layer to complete said metallization in the fabrication of said integrated circuit device.

12. The method according to claim 11 wherein said semiconductor device structures include silicided gate electrodes and associated silicided source and drain regions.

13. The method according to claim 11 wherein said semiconductor device structures include silicided gate electrodes and associated silicided source and drain regions and lower level metallization.

14. The method according to claim 11 wherein said step of depositing said titanium nitride barrier layer comprising alternating layers of titanium nitride and titanium containing a trace of nitrogen and comprises within a single sputtering chamber:
turning on a N₂ gas flow and thereby depositing a layer of titanium nitride; and
turning off said N₂ gas flow and thereby depositing a titanium layer containing a trace of nitrogen.

15. The method according to claim 14 wherein said during said step of turning on said N₂ gas flow, radio frequency power of a first rate is applied and wherein during said step of turning off said N₂ gas flow, radio frequency power of a second rate higher than said first rate is applied.

16. The method according to claim 15 wherein said first rate is about 6.5 kilowatts and wherein said second rate is about 8 kilowatts.

17. The method according to claim 11 wherein said discontinuous grain structure of said titanium nitride barrier layer prevents diffusion from said metal layer into said insulating layer.

18. The method according to claim 12 wherein said metal layer is selected from the group containing: tungsten, copper, and AlCu.

19. A method of metallization in the fabrication of an integrated circuit device comprising:
providing semiconductor device structures in and on a substrate;
covering said semiconductor device structures with an insulating layer;
opening a via through said insulating layer to one of said underlying semiconductor device structures;
conformally depositing a titanium nitride barrier layer having a discontinuous grain structure within said via wherein said titanium nitride barrier layer comprises alternating layers of titanium nitride and titanium containing a trace of nitrogen; and
depositing a metal layer overlying said titanium nitride barrier layer wherein said discontinuous grain structure of said titanium nitride barrier layer prevents diffusion from said metal layer into said insulating layer to complete said metallization in the fabrication of said integrated circuit device.

20. The method according to claim 19 wherein said semiconductor device structures include silicided gate electrodes and associated silicided source and drain regions.

21. The method according to claim 19 wherein said semiconductor device structures include silicided gate electrodes and associated silicided source and drain regions and lower level metallization.

22. The method according to claim 19 wherein said step of depositing said titanium nitride barrier layer comprising alternating layers of titanium nitride and titanium containing a trace of nitrogen and comprises within a single sputtering chamber:
turning on a N₂ gas flow and thereby depositing a layer of titanium nitride; and
turning off said N₂ gas flow and thereby depositing a titanium layer containing a trace of nitrogen.

23. The method according to claim 22 wherein said during said step of turning on said N₂ gas flow, radio frequency power of a first rate is applied and wherein during said step of turning off said N₂ gas flow, radio frequency power of a second rate higher than said first rate is applied.

24. The method according to claim 22 wherein said first rate is about 6.5 kilowatts and wherein said second rate is about 8 kilowatts.

25. The method according to claim 19 wherein said metal layer is selected from the group containing: tungsten, copper, and AlCu.
